(19) United States
(12) Patent Application Publication
(10) Pub. No.: US 2015/0053466 A1
(43) Pub. Date: Feb. 26, 2015

(54) PRINTED CIRCUIT BOARD AND METHOD FOR MANUFACTURING SAME

(71) Applicants: FUKUI PRECISION COMPONENT (SHENZHEN) CO., LTD., Shenzhen (CN); ZHEN DING TECHNOLOGY CO., LTD., Tayuan (TW)

(72) Inventors: MING-JAAN HO, New Taipei (TW); XIAN-QIN HU, Shenzhen (CN); JIAN LUO, Shenzhen (CN); FU-YUN SHEN, Shenzhen (CN)

(21) Appl. No.: 14/465,794

(22) Filed: Aug. 21, 2014

(30) Foreign Application Priority Data
Aug. 21, 2013 (CN) 2013103647451

(51) Int. Cl. H05K 1/02; H05K 3/02; H05K 1/09

(52) U.S. Cl. CPC H05K 1/0274; H05K 1/09; H05K 3/02; H05K 2201/0145; H05K 2201/0108
USPC 174/255; 29/847

(57) ABSTRACT

A printed circuit board (PCB) and a method for manufacturing the PCB are disclosed. A PCB includes a transparent insulating substrate, a conductive circuit layer 16, and a transparent cover layer. The conductive circuit layer is located between the transparent insulating substrate and the transparent cover layer. The conductive circuit layer includes a first Ni—W alloy pattern layer, a copper pattern layer, and a second Ni—W alloy pattern layer. The first Ni—W alloy pattern layer is adhered with the transparent adhesive layer. Bottom surfaces of the conductive pattern layer are coated by the first Ni—W alloy pattern layer. Top surfaces and side surfaces of conductive pattern layer are coated by the second Ni—W alloy pattern layer.

### FIELD

The present disclosure relates to a printed circuit board (PCB) and a method for manufacturing the PCB.

### BACKGROUND

A clear and transparent material can be employed to manufacture a PCB and can be used as a substrate and a cover film of the PCB, and, as such, the PCB can appear to be transparent.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a cross-sectional view of a copper clad lamination, according to an embodiment.

FIG. 2 shows a cross-sectional view of an etching resist layer formed on a copper layer of the copper clad lamination of FIG. 1.

FIG. 3 shows a cross-sectional view of a conductive pattern layer formed by etching a conductive layer in FIG. 2.

FIG. 4 is a cross-sectional view showing removal of the etching resist layer in FIG. 3, to obtain a PCB.

FIG. 5 shows a cross-sectional view of a second Ni—W alloy pattern layer formed on the conductive pattern layer in FIG. 4.

FIG. 6 shows a cross-sectional view of a cover layer formed on second Ni—W alloy pattern layer in FIG. 5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure is described in relation to a method for making a PCB, including providing a copper clad lamination including a transparent insulating substrate and a conductive layer including a copper layer and a Nickel-Tungsten (Ni—W) alloy layer, the Ni—W alloy layer being located between the transparent insulating substrate and the copper layer; removing portions of the conductive layer to obtain a conductive pattern layer including a copper pattern layer and a first Ni—W alloy pattern layer corresponding to the copper pattern layer, the conductive pattern layer comprising a top surface away from the transparent insulating substrate, and two side surfaces being perpendicular to and connected to the top surface; forming a second Ni—W alloy pattern layer on the top surface and the side surfaces of the conductive pattern layer, to obtain a conductive circuit layer including the first Ni—W alloy pattern layer, the copper pattern layer, and the second Ni—W alloy pattern layer; forming a transparent cover layer on the conductive circuit layer, to obtain a PCB.

A light transmittance of the transparent insulating substrate is greater than about 90 percent. A light transmittance of the transparent cover layer is greater than about 90 percent.

The copper clad lamination further comprises a transparent adhesive layer adhered between the transparent insulating substrate and the conductive layer.

A light transmittance of the transparent adhesive layer is greater than about 90 percent.

Portions of the conductive layer are removed by an etching process.

Before the portions of the conductive layer are removed, an etching resist layer is formed on a surface of the copper layer, then, the etching resist layer is patterned by an exposing process and then a developing process to form a patterned etching resist layer, then the portions of the conductive layer that are exposed from the patterned etching resist layer are removed by an etching process, and the reserved portions of the conductive layer is to be the conductive pattern layer, then the patterned etching resist layer is removed.

The second Ni—W alloy pattern layer is formed by an electric plating process.

The present disclosure is also described in relation to a PCB. The PCB includes a transparent insulating substrate, a conductive circuit layer, and a transparent cover layer. The conductive circuit layer is located between the transparent insulating substrate and the transparent cover layer. The conductive circuit layer comprising a first Ni—W alloy pattern layer, a copper pattern layer, and a second Ni—W alloy pattern layer. The first Ni—W alloy pattern layer is adhered with the transparent adhesive layer. Bottom surfaces of the conductive pattern layer are coated by the first Ni—W alloy pattern layer, and top surfaces and side surfaces of conductive pattern layer are coated by the second Ni—W alloy pattern layer.

A light transmittance of the transparent insulating substrate is greater than about 90 percent. A light transmittance of the transparent cover layer is greater than about 90 percent.

The transparent insulating substrate and the transparent cover layer are all made of transparent PET.

A transparent adhesive layer is adhered between the transparent insulating substrate and the conductive layer.

A light transmittance of the transparent adhesive layer is greater than about 90 percent.

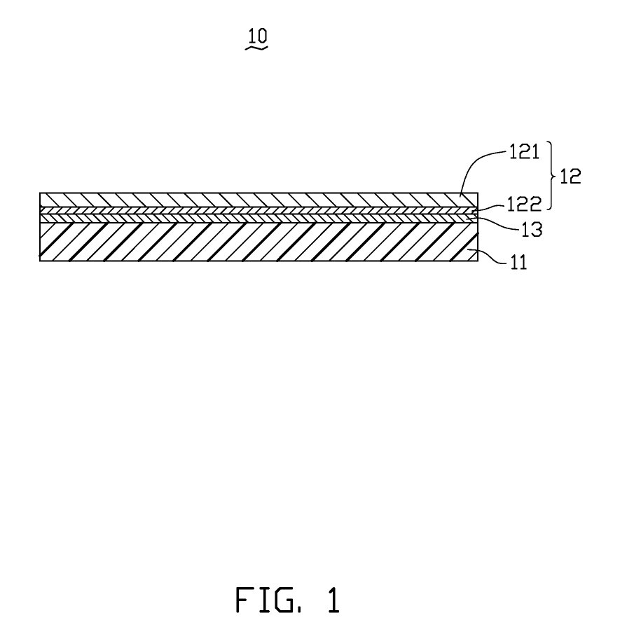

FIGS. 1-6 illustrate a method for manufacturing a PCB in accordance with an embodiment.

FIG. 1 shows a copper clad lamination 10 being provided. The copper clad lamination 10 includes a transparent insulating substrate 11, a conductive layer 12, and a transparent adhesive layer 13 adhered between the transparent insulating substrate 11 and the conductive layer 12.

The transparent insulating substrate 11 can be made of transparent flex resin or transparent rigid resin. The transparent flex resin can be transparent polyethylene terephthalate (PET). The transparent rigid resin can be transparent rigid epoxy. A light transmittance of the transparent insulating substrate 111 is greater than about 90 percent.

The conductive layer 12 includes a copper layer 121 and a Ni—W alloy layer 122. The Ni—W alloy layer 122 is adhered with the transparent adhesive layer 13. The copper layer 121 is located on a surface of the Ni—W alloy layer 122 away from the transparent adhesive layer 13. In this embodiment, the conductive layer 12 is formed by electrical plating the Ni—W alloy layer 122 on the copper layer 121.

The transparent adhesive layer 13 is a transparent bonding sheet. The transparent adhesive layer 13 can be made of transparent epoxy, transparent acrylic resin, or a mixture. A light transmittance of the transparent adhesive layer 13 is greater than about 90 percent. The transparent adhesive layer 13 is adhered between the transparent insulating substrate 11 and the Ni—W alloy layer 122.

In other embodiments, the transparent adhesive layer 13 can be omitted, and the conductive layer 12 can be directly laminated on the surface of the transparent insulating substrate 11.

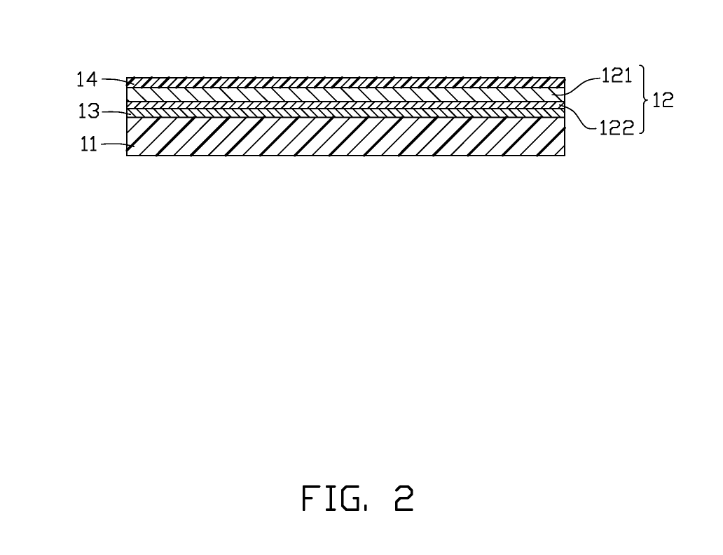

FIGS. 2 to 4 illustrate the conductive layer 12 being manufactured to a conductive pattern layer 15 by removing portions of the conductive layer 12, to obtain a printed circuit substrate 20.

FIG. 2 illustrates that an etching resist layer 14 is formed on a surface of the copper layer 121. In this embodiment, the etching resist layer 14 is a dry film, and is laminated on the surface of the copper layer 121.

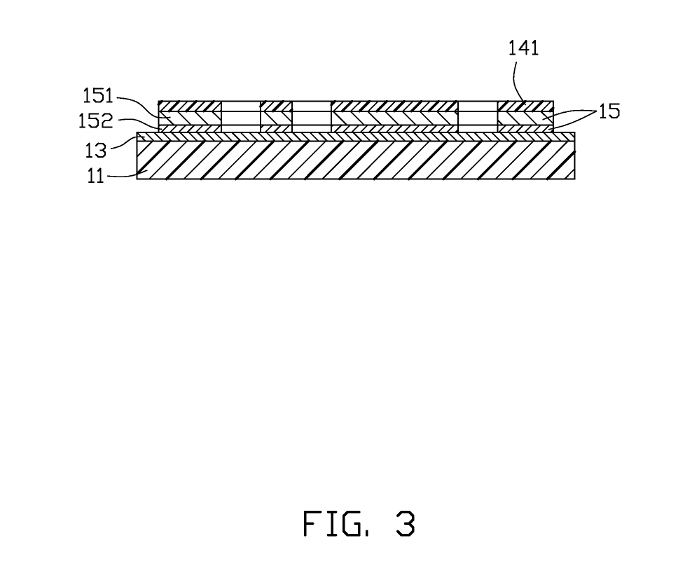

FIG. 3 illustrates that a conductive pattern layer 15 is formed by etching portions of the conductive layer 12. In this embodiment, first, the etching resist layer 14 is patterned by an exposing process and then a developing process, to form a patterned etching resist layer 141; then, the portions of the conductive layer 12 that are exposed from the patterned etching resist layer 141 are removed by an etching process, and the reserved portions of the conductive layer 12 is the conductive pattern layer 15, that is, the copper layer 121 is etched to be a copper pattern layer 151, and the Ni—W alloy layer 122 is etched to be a first Ni—W alloy pattern layer 152, the copper pattern layer 151 is corresponding to the first Ni—W alloy pattern layer 152, the conductive pattern layer 15 includes the copper pattern layer 151 and the first Ni—W alloy pattern layer 152.

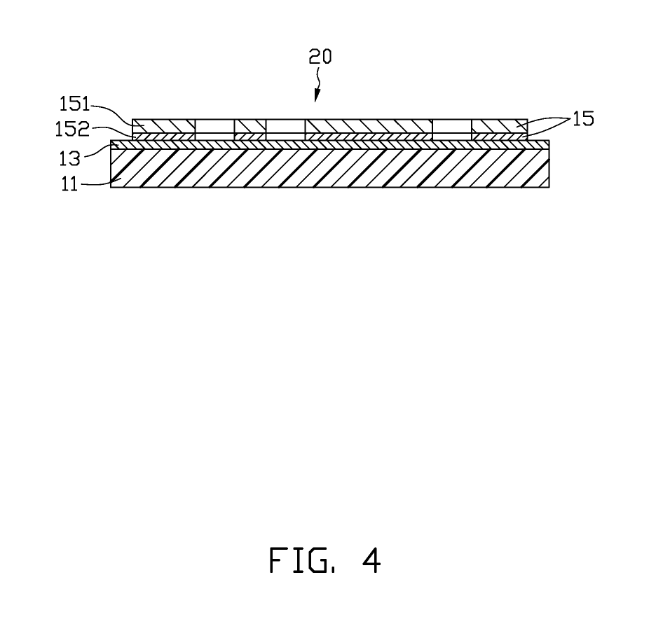

FIG. 4 illustrates when the patterned etching resist layer 141 is removed, a printed circuit substrate 20 is obtained.

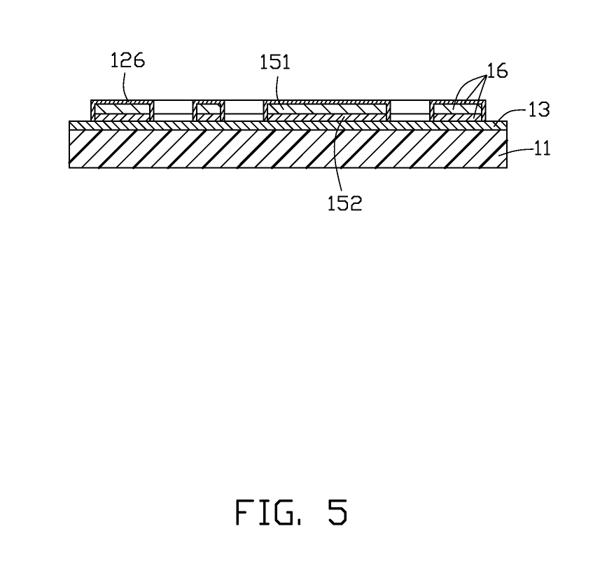

FIG. 5 illustrates a second Ni—W alloy pattern layer 126 being formed on top surfaces and side surfaces of the conductive pattern layer 15, then, bottom surfaces of the conductive pattern layer 15 are coated by the first Ni—W alloy pattern layer 152, and the top surfaces and side surfaces of conductive pattern layer 15 are coated by the second Ni—W alloy pattern layer 126, that is, all surfaces of the conductive pattern layer 15 are coated by Ni—W alloy, to obtain a conductive circuit layer 16. The conductive circuit layer 16 includes the first Ni—W alloy pattern layer 152, the copper pattern layer 151, and the second Ni—W alloy pattern layer 152. The color of the conductive circuit layer 16 is gray, which is same to the color of the Ni—W alloy.

The second Ni—W alloy pattern layer 126 can be formed by an electric plating process. In detail, first, the top surfaces and side surfaces of the conductive pattern layer 15 can be cleaned by an abrasive blasting process. Then, the printed circuit substrate 20 can be dipped in a Ni—W electric plating solution to form the second Ni—W alloy pattern layer 126 on the top surfaces and side surfaces of the conductive pattern layer 15. The Ni—W electric plating solution can include NiSO₄, NaWO₄, NH₄OH, and chelating agent. The chelating agent can be citric acid. In this embodiment, the Ni—W electric plating solution can be contained in a hull cell.

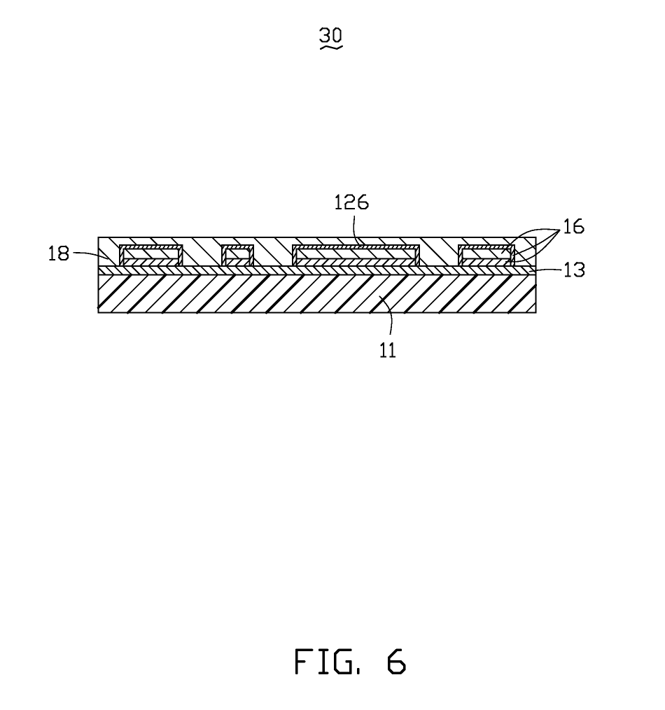

FIG. 6 illustrates a transparent cover layer 18 being formed on the conductive circuit layer 16, to obtain a PCB 30.

The transparent cover layer 18 can be made of transparent PET. A light transmittance of the transparent cover layer 18 is greater than about 90 percent. The transparent cover layer 18 can be formed on top surfaces of the conductive circuit layer 16 by a lamination process. The transparent cover layer 18 can include an adhesive material, and the adhesive material can be adhered on the top surfaces of the conductive circuit layer 16 and can fill gaps between circuits of the conductive circuit layer 16.

FIG. 6 illustrates that the PCB 30 includes a transparent insulating substrate 11, a transparent adhesive layer 13, a conductive circuit layer 16, and a transparent cover layer 18. The transparent adhesive layer 13 is adhered between the transparent insulating substrate 11 and the conductive circuit layer 16. The conductive circuit layer 16 is located between the transparent insulating substrate 11 and the transparent cover layer 18. The conductive circuit layer 16 includes a first Ni—W alloy pattern layer 152, a copper pattern layer 151, and a second Ni—W alloy pattern layer 152. The first Ni—W alloy pattern layer is adhered with the transparent adhesive layer 13. The conductive pattern layer 15 includes a bottom surface adhered with the transparent insulating substrate 11, a top surface away from the transparent insulating substrate and opposite to the bottom surface, and two side surfaces being perpendicular to and connected to the top surface. The bottom surfaces of the conductive pattern layer 15 are coated by the first Ni—W alloy pattern layer 152, and the top surfaces and the side surfaces of conductive pattern layer 15 are coated by the second Ni—W alloy pattern layer 126, that is, all surfaces of the conductive pattern layer 15 are coated by Ni—W alloy.

The PCB 30 can appear to be transparent to the human eye, by employing the transparent insulating layer 11, the transparent adhesive layer 13, and the transparent cover layer 18. The transparence of the PCB 30 can be enhanced by employing the conductive circuit layer 16, for the color of the conductive circuit layer 16 is gray, compare to the conventional black conductive circuit layer; the gray conductive circuit layer 16 can easily escape the human eye.

In other embodiments, the number of the conductive circuit layers 16 can be more than one, then, the number of the insulating layers 11 can also be more than one, and any two adjacent conductive circuit layers 16 can be spaced by one insulating layer 11. The more than one conductive circuit layers 16 and the more than one insulating layer 11 can be formed by a build up process.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A method for making a printed circuit board (PCB), comprising:
providing a copper clad lamination comprising a transparent insulating substrate and a conductive layer comprising a copper layer and a Nickel-Tungsten (Ni—W) alloy layer located between the transparent insulating substrate and the copper layer;
removing portions of the conductive layer to obtain a conductive pattern layer comprising a copper pattern layer and a first Ni—W alloy pattern layer corresponding to the copper pattern layer, the conductive pattern layer comprising a top surface away from the transparent insulating substrate, and two side surfaces being perpendicular to and connected to the top surface;
forming a second Ni—W alloy pattern layer on the top surface and the side surfaces of the conductive pattern layer to obtain a conductive circuit layer comprising the first Ni—W alloy pattern layer, the copper pattern layer, and the second Ni—W alloy pattern layer; and
forming a transparent cover layer on the conductive circuit layer to obtain a PCB.

2. The method of claim 1, wherein a light transmittance of the transparent insulating substrate is greater than about 90 percent, a light transmittance of the transparent cover layer is greater than about 90 percent.

3. The method of claim 1, wherein the copper clad lamination further comprises a transparent adhesive layer adhered between the transparent insulating substrate and the conductive layer.

4. The method of claim 3, wherein a light transmittance of the transparent adhesive layer is greater than about 90 percent.

5. The method of claim 1, wherein portions of the conductive layer are removed by an etching process.

6. The method of claim 5, wherein before the portions of the conductive layer are removed, an etching resist layer is formed on a surface of the copper layer, then, the etching resist layer is patterned by an exposing process and then a developing process to form a patterned etching resist layer, then the portions of the conductive layer that are exposed from the patterned etching resist layer are removed by an etching process, and the reserved portions of the conductive layer is to be the conductive pattern layer, then the patterned etching resist layer is removed.

7. The method of claim 1, wherein the second Ni—W alloy pattern layer is formed by an electric plating process.

8. A printed circuit board (PCB) comprising:
a transparent insulating substrate;
a conductive circuit layer; and
a transparent cover layer;
wherein the conductive circuit layer being located between the transparent insulating substrate and the transparent cover layer, the conductive circuit layer 16 comprising a first Ni—W alloy pattern layer, a copper pattern layer, and a second Ni—W alloy pattern layer, the first Ni—W alloy pattern layer being adhered with the transparent adhesive layer, bottom surfaces of the conductive pattern layer being coated by the first Ni—W alloy pattern layer, top surfaces and side surfaces of conductive pattern layer being coated by the second Ni—W alloy pattern layer.

9. The PCB of claim 8, wherein a light transmittance of the transparent insulating substrate is greater than about 90 percent, a light transmittance of the transparent cover layer is greater than about 90 percent.

10. The PCB of claim 9, wherein the transparent insulating substrate and the transparent cover layer are all made of transparent PET.

11. The PCB of claim 8, further comprising a transparent adhesive layer adhered between the transparent insulating substrate and the conductive layer.

12. The PCB of claim 11, wherein a light transmittance of the transparent adhesive layer is greater than about 90 percent.
